(19) United States
(12) Patent Application Publication
(10) Pub. No.: US 2023/0361757 A1
(43) Pub. Date: Nov. 9, 2023

(54) Partially Suspending a Piezoelectric Layer Using a Dielectric

(71) Applicant: RF360 EUROPE GMBH, Munich (DE)

(72) Inventors: Benno Blaschke, Munich (DE); Soeren Zimmermann, Munich (DE); Willi Aigner, Moosinning (DE)

(21) Appl. No.: 17/662,540

(22) Filed: May 9, 2022

(51) Int. Cl. H03H 3/02; H03H 9/02; H03H 9/17; H03H 9/13; H03H 9/56

(52) U.S. Cl. CPC H03H 9/564; H03H 3/02; H03H 9/02149; H03H 9/02228; H03H 9/132; H03H 9/173; H03H 9/175; H03H 2003/021

(57) ABSTRACT

An apparatus is disclosed for partially suspending a piezoelectric layer using a dielectric. In an example aspect, the apparatus includes a microacoustic filter with a substrate layer, a piezoelectric layer, an electrode structure that is in contact with the piezoelectric layer, and a dielectric. The electrode structure includes multiple fingers arranged across a plane having a first axis that is perpendicular to the multiple fingers and a second axis that is parallel to the multiple fingers. The dielectric is configured to separate the piezoelectric layer from the substrate layer and define a cavity between the piezoelectric layer and the substrate layer. The dielectric is also configured to support the piezoelectric layer across at least three points along the first axis.

### TECHNICAL FIELD

This disclosure relates generally to wireless transceivers and other components that employ filters and, more specifically, to a microacoustic filter with a dielectric that partially suspends a piezoelectric layer apart from a substrate layer.

### BACKGROUND

Electronic devices use radio-frequency (RF) signals to communicate information. These radio-frequency signals enable users to talk with friends, download information, share pictures, remotely control household devices, and receive global positioning information. To transmit or receive the radio-frequency signals within a given frequency band, the electronic device may use filters to pass signals within the frequency band and to suppress (e.g., attenuate) jammers or noise having frequencies outside of the frequency band. It can be challenging, however, to design a filter that provides filtering for radio-frequency applications, including those that utilize frequencies above 2 gigahertz (GHz).

### SUMMARY

An apparatus is disclosed that implements techniques for partially suspending a piezoelectric layer using a dielectric. In example implementations, a microacoustic filter includes a substrate layer, a piezoelectric layer, and a dielectric. The dielectric at least partially covers the piezoelectric layer and partially suspends the piezoelectric layer “above” or apart from the substrate layer. Due to the partial coverage and partial suspension, a cavity is present between the dielectric and the substrate layer.

With the partially-suspended piezoelectric layer, the microacoustic filter can excite and confine a plate mode and have a larger pitch at frequencies above, e.g., 2 GHz relative to other microacoustic filters that excite surface-acoustic-wave modes. This larger pitch can make it easier to manufacture an electrode structure of the microacoustic filter. Furthermore, the microacoustic filter can have improved mechanical stability, improved thermal management, and a smaller absolute value of a temperature coefficient of frequency relative to other acoustic filters with fully-suspended piezoelectric layers.

In an example aspect, an apparatus for filtering is disclosed. The apparatus includes a microacoustic filter with a substrate layer, a piezoelectric layer, an electrode structure that is in contact with the piezoelectric layer, and a dielectric. The electrode structure includes multiple fingers arranged across a plane having a first axis that is perpendicular to the multiple fingers and a second axis that is parallel to the multiple fingers. The dielectric is configured to separate the piezoelectric layer from the substrate layer and define a cavity between the piezoelectric layer and the substrate layer. The dielectric is also configured to support the piezoelectric layer across at least three points along the first axis.

In an example aspect, an apparatus for filtering is disclosed. The apparatus includes a microacoustic filter configured to generate a filtered signal from a radio-frequency signal. The microacoustic filter includes means for converting the radio-frequency signal to an acoustic wave and converting a formed acoustic wave into the filtered signal. The microacoustic filter also includes means for exciting an antisymmetric plate mode. The microacoustic filter additionally includes means for confining energy of the antisymmetric plate mode within the means for exciting. The microacoustic filter further includes means for partially suspending the means for exciting apart from the means for confining energy.

In an example aspect, a method for manufacturing a microacoustic filter is disclosed. The method includes providing a substrate layer and providing a piezoelectric layer. The method also includes providing an electrode structure having multiple fingers arranged across a plane. The plane is defined by a first axis that is perpendicular to the multiple fingers and a second axis that is parallel to the multiple fingers. The electrode structure is in contact with the piezoelectric layer. The method additionally includes providing a dielectric that separates the piezoelectric layer from the substrate layer, defines a cavity between the piezoelectric layer and the substrate layer, and supports the piezoelectric layer across at least three points along the first axis.

In an example aspect, a microacoustic filter is disclosed. The microacoustic filter includes an electrode structure, a substrate layer, a piezoelectric layer, and a dielectric. The electrode structure includes multiple fingers arranged across a plane having a first axis that is perpendicular to the multiple fingers and a second axis that is parallel to the multiple fingers. The piezoelectric layer has a surface that faces the substrate layer. The dielectric includes an intermediate layer and at least three pillars. The intermediate layer is disposed across the surface of the piezoelectric layer. The intermediate layer has a surface that faces the substrate layer. The at least three pillars extend past a plane defined by the surface of the intermediate layer and toward the substrate layer to define a cavity between the intermediate layer and the substrate layer. The at least three pillars are positioned across at least three points along the first axis.

### BRIEF DESCRIPTION OF DRAWINGS

FIG. 1 illustrates an example operating environment for partially suspending a piezoelectric layer using a dielectric.

FIG. 2 illustrates an example wireless transceiver including at least one microacoustic filter with a dielectric that partially suspends a piezoelectric layer.

FIGS. 3-1 illustrates example components of a microacoustic filter with a dielectric that partially suspends a piezoelectric layer.

FIGS. 3-2 illustrates example Euler angles that define an orientation of piezoelectric material of a microacoustic filter.

FIG. 4 illustrates a first example implementation of a microacoustic filter with a dielectric that partially suspends a piezoelectric layer.

FIG. 5 illustrates examples of an intermediate layer and pillars of a dielectric that partially suspend a piezoelectric layer.

FIG. 6 illustrates a second example implementation of a microacoustic filter with a dielectric that partially suspends a piezoelectric layer.

FIG. 7 illustrates a third example implementation of a microacoustic filter with a dielectric that partially suspends a piezoelectric layer.

FIG. 8 illustrates a fourth example implementation of a microacoustic filter with a dielectric that partially suspends a piezoelectric layer.

FIG. 9 is a flow diagram illustrating an example process for manufacturing a microacoustic filter with a dielectric that partially suspends a piezoelectric layer.

### DETAILED DESCRIPTION

To transmit or receive radio-frequency signals within a given frequency band, an electronic device may use filters to pass signals within the frequency band and to suppress (e.g., attenuate) jammers or noise having frequencies outside of the frequency band. Electroacoustic devices (e.g., “acoustic filters”) can be used to filter highfrequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using a piezoelectric material, the acoustic filter operates by transforming an electrical signal wave that is applied to an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electromagnetic and acoustic waves.

The acoustic wave features a velocity having a magnitude that is significantly less than that of a velocity of the electromagnetic wave. Generally, the magnitude of the propagation velocity of a wave is proportional to a size of a wavelength of the wave. Consequently, after conversion of the electrical signal wave into the acoustic signal wave, the wavelength of the acoustic signal wave is significantly smaller than the wavelength of the electrical signal wave. The resulting smaller wavelength of the acoustic signal wave enables filtering to be performed using a smaller filter device. This permits acoustic filters to be used in space-constrained devices, including portable electronic devices such as cellular phones.

It can be challenging, however, to design an acoustic filter that can provide filtering for higher frequencies, such as those used in frequency bands 7, 40, n77, and n79; with Wi-Fi® at 2.4 gigahertz (GHz); with 5 GHz frequencies; at sub-6 GHz frequencies, and/or at frequencies between 6 and 13 GHz. In particular, a pitch of the electrode structure can become too small or potentially less practical or costly for the manufacturing equipment to accurately produce due to lithographic constraints. The pitch can also introduce problems involving electrostatic discharge or power durability.

To address this challenge, some techniques implement an acoustic filter with a piezoelectric layer that is fully-suspended and excites and confines a plate mode. To fully suspend the piezoelectric layer, the acoustic filter has supports positioned at two opposite edges of the piezoelectric layer along a direction of acoustic-wave propagation. With only two supports at the outer edges of the piezoelectric layer, however, this design can be mechanically unstable.

The full suspension of the piezoelectric layer can also result in a larger absolute value of a temperature coefficient of frequency (TCF) compared to other acoustic filters with non-suspended piezoelectric layers. The temperature coefficient of frequency characterizes an amount a resonant frequency or filter skirt changes in response to a change in temperature. A filter with a smaller absolute value of the temperature coefficient of frequency has a more stable frequency response over a range of temperatures compared to another filter with a larger absolute value of the temperature coefficient of frequency.

To provide certain performance improvements, techniques for partially suspending a piezoelectric layer using a dielectric are described. In example implementations, a microacoustic filter includes a substrate layer, an electrode structure, a piezoelectric layer, and a dielectric. The dielectric at least partially covers or abuts the piezoelectric layer and partially suspends the piezoelectric layer “above” or apart from the substrate layer. Due to the partial coverage and partial suspension, a cavity is present between the dielectric and the substrate layer. The partial coverage enables the microacoustic filter to have a smaller absolute value of the temperature coefficient of frequency relative to another acoustic filter with the fully-suspended piezoelectric layer.

In contrast to a fully-suspended piezoelectric layer, the partially-suspended piezoelectric layer is supported by the dielectric across three or more points along an axis that is normal to a longitudinal axis of fingers of the electrode structure. The additional point(s) of support enable the microacoustic filter to have improved mechanical stability, thermal management, and power dissipation relative to another acoustic filter with a fully-suspended piezoelectric layer. In some cases, one or more of the dielectric supports can be positioned “below” a portion of the electrode structure of the microacoustic filter (e.g., between a finger of the electrode structure and the substrate layer).

With the techniques of partially suspending the piezoelectric layer using the dielectric, the microacoustic filter can excite and confine a plate mode. The plate mode enables the microacoustic filter to have a larger pitch at frequencies above, e.g., 2 GHz compared to another microacoustic filter that excites a surface-acoustic-wave mode, such as a Rayleigh mode or a shear mode. This larger pitch can make it easier to manufacture the electrode structure of the microacoustic filter. Furthermore, by partially suspending the piezoelectric layer, the microacoustic filter can have improved mechanical stability, improved thermal management, and a smaller absolute value of a temperature coefficient of frequency relative to another acoustic filter with a fully-suspended piezoelectric layer. These techniques can be used with, and provide benefits for, microacoustic filters that support frequencies above 2 GHz as well as for other microacoustic filters that support frequencies below 2 GHz.

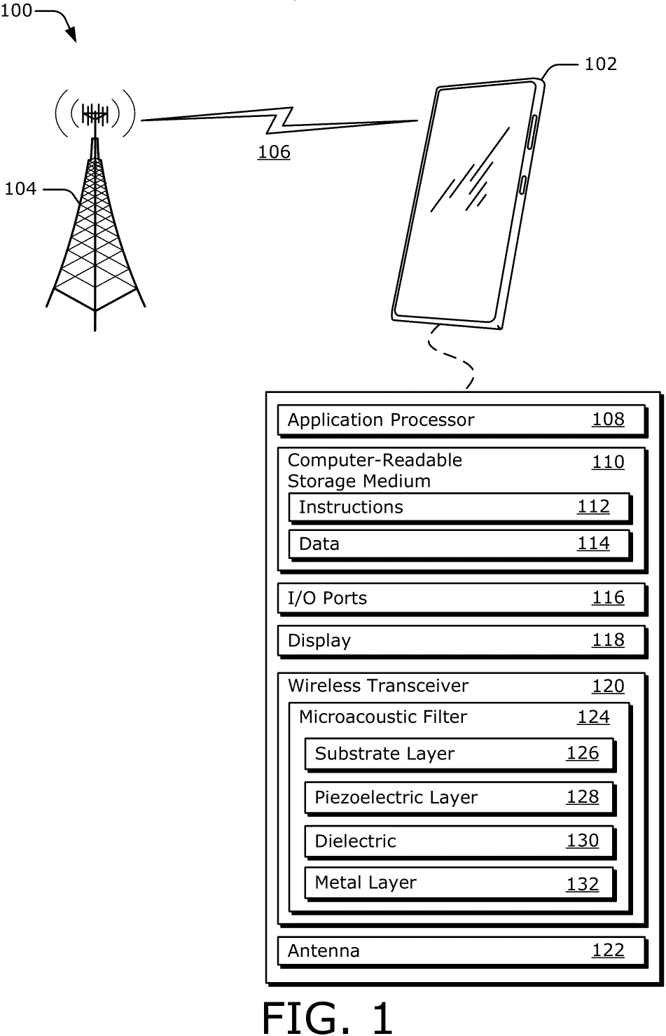

FIG. 1 illustrates an example environment 100 for partially suspending a piezoelectric layer using a dielectric. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), or 5th-generation (5G) cellular; IEEE 802.11 (e.g., Wi-Fi®); IEEE 802.15 (e.g., Bluetooth®); IEEE 802.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), nonvolatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one microacoustic filter 124 (e.g., an acoustic filter, a plate-mode acoustic-wave filter, or a membrane-type filter). In some implementations, the wireless transceiver 120 includes multiple microacoustic filters 124, which can be formed from microacoustic resonators arranged in series, in parallel, in a ladder structure, in a lattice structure, or some combination thereof. Although the microacoustic filter 124 can be any type of microacoustic filter, the techniques for partially suspending a piezoelectric layer using a dielectric can be particularly advantageous for confining a plate mode acoustic wave within the piezoelectric layer 128. One such example acoustic mode is a plate mode, such as an antisymmetric plate mode (e.g., an antisymmetric Lamb mode). The antisymmetric plate mode can be a first order (e.g., A1) mode or a higher order mode (e.g., A3). The antisymmetric plate mode excites an acoustic wave that causes different portions (e.g., an upper portion and a lower portion) of the piezoelectric layer 128 to move in opposite directions along a horizontal dimension. The antisymmetric plate mode is a quasi-stationary mode with approximately a zero group velocity.

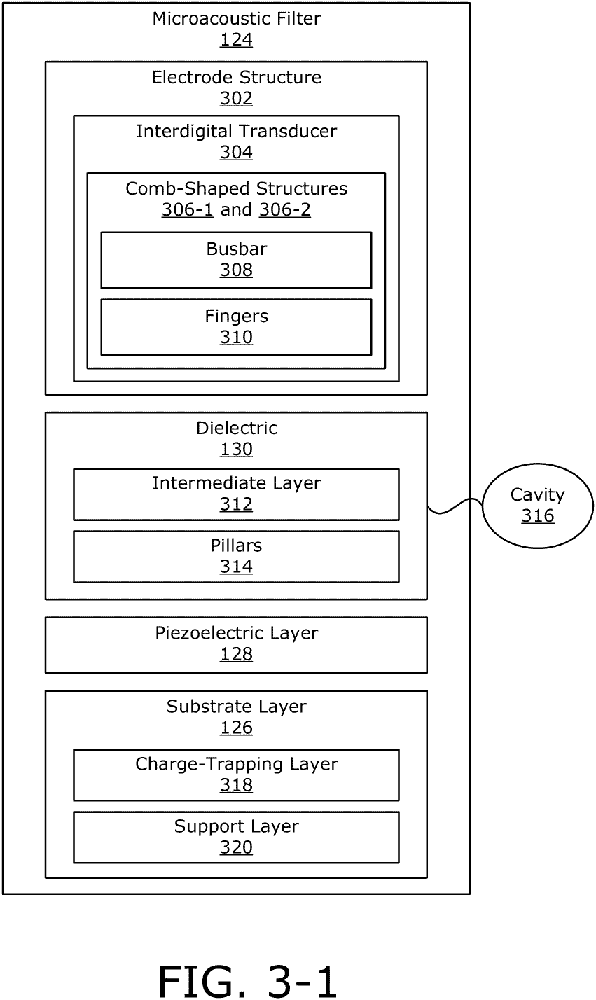

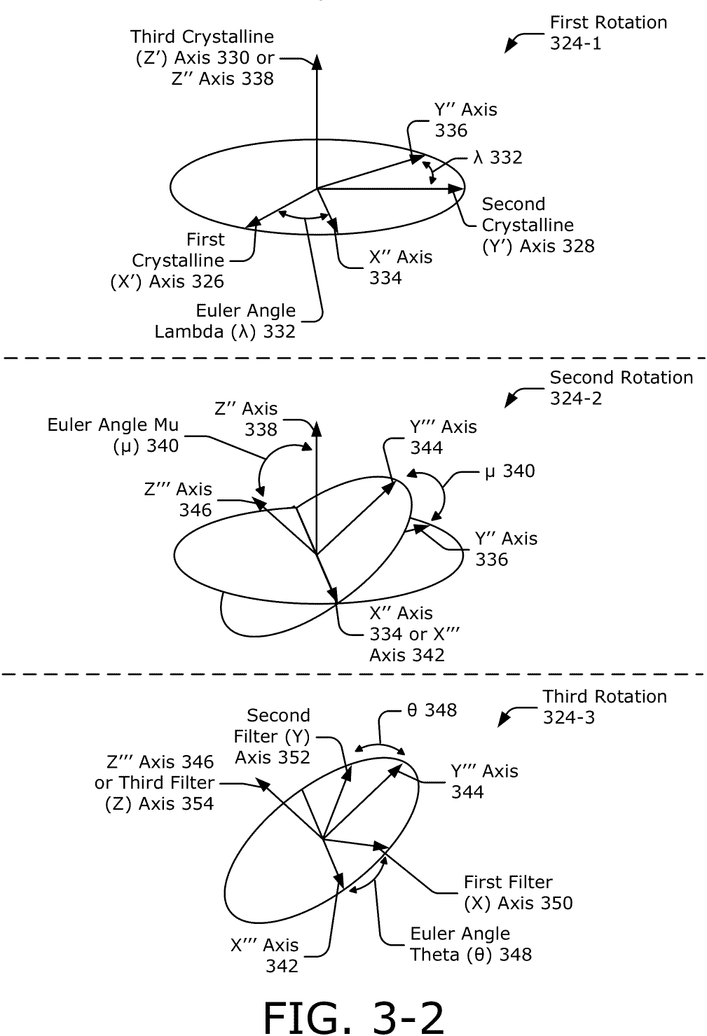

The microacoustic filter 124 includes at least one substrate layer 126, at least one piezoelectric layer 128, a dielectric 130 (e.g., dielectric material or at least one dielectric layer), and at least one metal layer 132. The dielectric 130 implements, at least partially, the techniques of partially suspending the piezoelectric layer 128. In particular, the dielectric 130 partially covers the piezoelectric layer 128 and partially suspends the piezoelectric layer 128 “above” or apart from the substrate layer 126. The dielectric 130 also defines or forms a cavity between the partially-covered piezoelectric layer 128 and the substrate layer 126. This cavity enables the piezoelectric layer 128 to excite the plate mode and confine the acoustic wave within the piezoelectric layer 128, which reduces acoustic losses. The metal layer 132 includes an electrode structure (e.g., an electrode structure 302 of FIGS. 3-1) and can be partially disposed within the dielectric 130, partially disposed within the piezoelectric layer 128, or both.

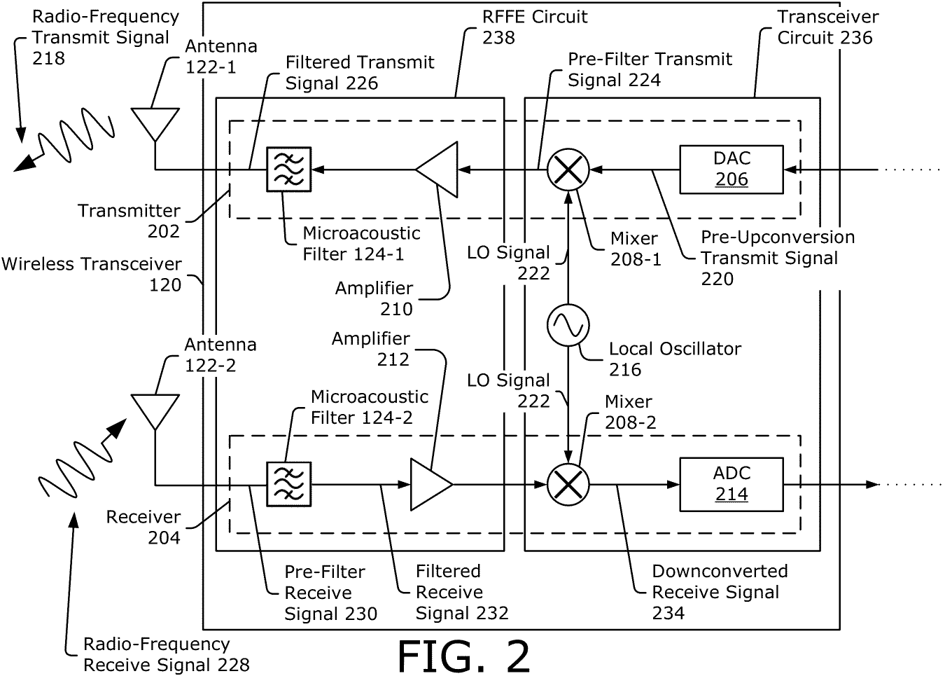

With the techniques of partially suspending the piezoelectric layer 128, the microacoustic filter 124 can have fewer lithographic constraints at higher frequencies compared to other microacoustic filters that excite surface-acoustic-wave modes. As such, the microacoustic filter 124 can be designed to support frequency ranges above 2 GHz, including frequencies between approximately 4 and 13 GHz (e.g., approximately 4, 7, 10, or 13 GHz). In general, the term “approximately” can mean that any of the frequencies can be within +/-10% of a specified value or less (e.g., within +/- 5%, +/-3%, or +/-2% of a specified value). The microacoustic filter 124 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first microacoustic filter 124-1. The receiver 204 includes at least one second microacoustic filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the microacoustic filter 124-1 of the transmitter 202, the microacoustic filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first microacoustic filter 124-1.

The first microacoustic filter 124-1 filters the amplified pre-filter transmit signal 224 to generate a filtered transmit signal 226. As part of the filtering process, the first microacoustic filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second microacoustic filter 124-2 accepts the received radio-frequency receive signal 228, which is represented by a pre-filter receive signal 230. The second microacoustic filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which microacoustic filters 124 may be included. For example, the microacoustic filters 124 can be integrated within duplexers or diplexers of the wireless transceiver 120. Example implementations of the microacoustic filter 124-1 or 124-2 are further described with respect to FIGS. 3 to 8.

FIGS. 3-1 illustrates example components of the microacoustic filter 124. In the depicted configuration, the microacoustic filter 124 includes an electrode structure 302, the dielectric 130 (e.g., dielectric material), the piezoelectric layer 128, and the substrate layer 126. The electrode structure 302 comprises an electrically conductive material, such as metal, and can include one or more layers. The one or more layers can include one or more metal layers and can optionally include one or more adhesion layers. As an example, the metal layers can be composed of aluminium (Al), copper (Cu), silver (Ag), gold (Au), tungsten (W), or some combination or doped version thereof. The adhesion layers can be composed of chromium (Cr), titanium (Ti), molybdenum (Mo), or some combination thereof.

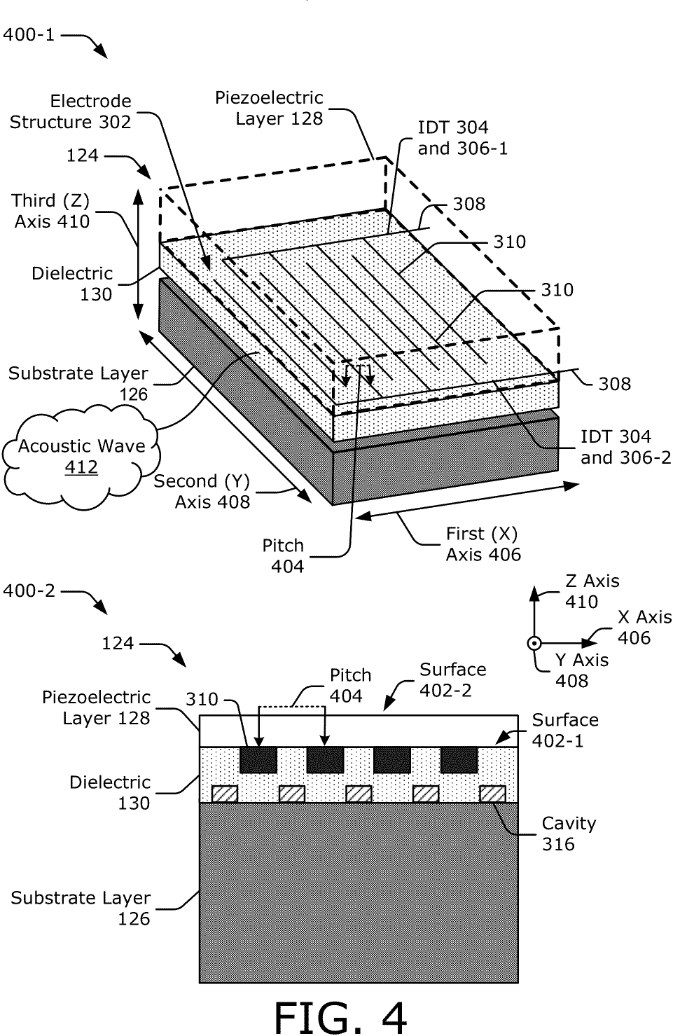

The electrode structure 302 can include one or more interdigital transducers 304. The interdigital transducer 304 converts an electrical signal into an acoustic wave and converts the acoustic wave into a filtered electrical signal. The interdigital transducer 304 includes at least two comb-shaped structures 306-1 and 306-2. Each comb-shaped structure 306-1 and 306-2 includes a busbar 308 (e.g., a conductive segment or rail) and multiple fingers 310 (e.g., electrode fingers). An example interdigital transducer 304 is further described with respect to FIG. 4. Although not explicitly shown, the electrode structure 302 can also include two or more reflectors. In an example implementation, the interdigital transducer 304 is arranged between two reflectors.

The dielectric 130 includes at least one intermediate layer 312 and at least three pillars 314. The intermediate layer 312 refers to a portion of the dielectric 130 that can be disposed on the piezoelectric layer 128. In general, the intermediate layer 312 adheres to the piezoelectric layer 128 and functions as a foundation or framework for partially suspending the piezoelectric layer 128.

A thickness of the intermediate layer 312 can be designed to achieve a particular temperature coefficient of frequency. In general, increasing a thickness of the intermediate layer 312 decreases an absolute value of the temperature coefficient of frequency. However, the thickness of the intermediate layer 312 can be limited to prevent spurious modes from negatively impacting performance.

The pillars 314 are disposed between the intermediate layer 312 and the substrate layer 126. The pillars 314 provide structural support to elevate the intermediate layer 312 above the substrate layer 126. By elevating the intermediate layer 312, the pillars 314 suspend at least a portion of the piezoelectric layer 128 apart from the substrate layer 126. The pillars 314 are positioned at different points along an axis that is normal to a longitudinal axis of the fingers 310 of the electrode structure 302. In this way, the pillars 314 improve the mechanical stability of the microacoustic filter 124 compared to other acoustic filters with fully-suspended piezoelectric layers.

The pillars 314 define a cavity 316 (or gap) between the intermediate layer 312 and the substrate layer 126. The cavity 316 can include a gas, such as air. The pillars 314 provide stability and support to prevent the cavity 316 from collapsing. In some implementations, at least one of the pillars 314 is positioned “below” one of the fingers 310. Sometimes, the quantity of pillars 314 equals a quantity of the fingers 310. In this case, each pillar 314 can be positioned “below” a corresponding finger 310. In general, positioning the pillar 314 below a portion of the electrode structure 302 can be advantageous as the acoustic wave (or plate wave) is spatially confined between the fingers 310 of the electrode structure 302. As such, this positioning can reduce the effects of the pillars 314 on the acoustic wave.

The dielectric 130 can be formed using a variety of different types of dielectric material, such as silicon dioxide (SiO₂), silicon nitride (Si₃N₄), aluminum oxide (Al₂O₃), aluminium nitride (AIN), or some combination or doped version thereof. Doped versions of silicon dioxide can include fluoride-doped silicon dioxide (e.g., silicon oxyfluoride (SiO₂F)) or carbon-doped silicon dioxide (e.g., silicon-oxicarbide (SiO₂C)). In some implementations, the dielectric 130 is composed of multiple layers. The multiple layers can be formed using the same material or different materials. Also, the intermediate layer 312 and the pillars 314 can be implemented using the same material or different materials. In example implementations, a total thickness of the dielectric 130 (e.g., a combined thickness of the intermediate layer 312 and the pillars 314) can be between approximately 50 nanometers and 1 micrometer. In general, the term “approximately” can mean that any of the thicknesses can be within +/-10% of a specified value or less (e.g., within +/- 5%, +/-3%, or +/-2% of a specified value).

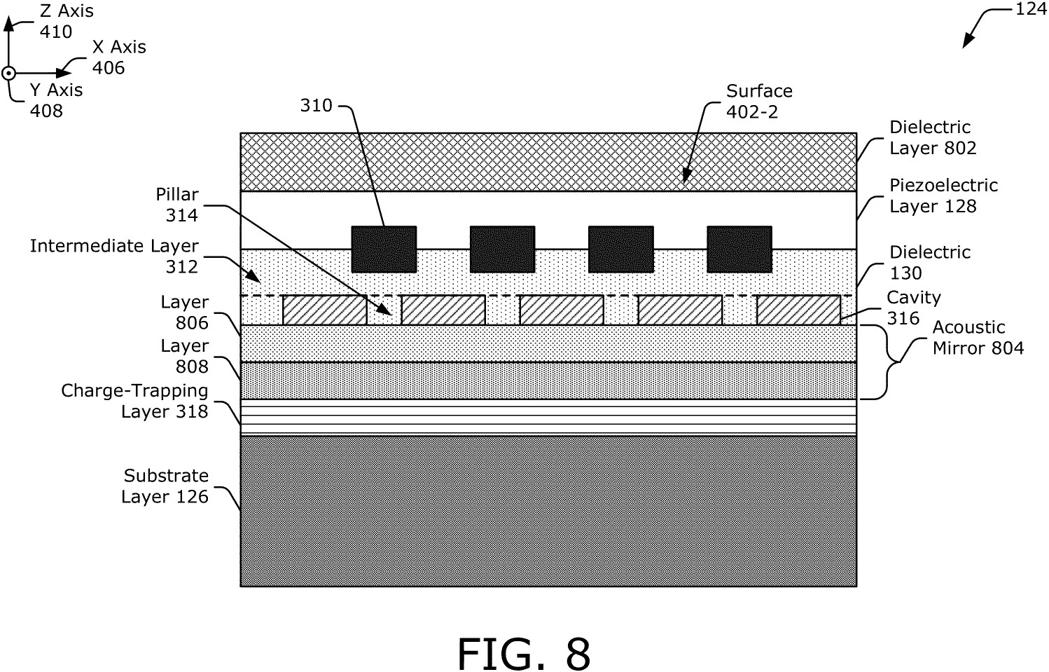

In some implementations, the microacoustic filter 124 includes additional dielectric layers, such as a dielectric layer shown in FIG. 8. This dielectric layer can also enable a target temperature coefficient of frequency to be achieved.

In example implementations, the piezoelectric layer 128 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), quartz, aluminium nitride (AIN), aluminium scandium nitride (AlScN), or some combination thereof. In general, the material that forms the piezoelectric layer 128 has a crystalline structure. This crystalline structure is defined by an ordered arrangement of particles (e.g., atoms, ions, or molecules). The crystalline structure of the piezoelectric layer 128 can be defined by Euler angles lambda (λ), mu (µ), and theta (θ).

In some aspects, the material and crystalline structure of the piezoelectric layer 128 are selected such that the piezoelectric layer 128 excites an antisymmetric plate mode. Consider two examples in which the piezoelectric layer 128 is formed using lithium niobate. In a first example implementation, the lithium niobate material is cut such that a value of the Euler angle mu (µ) is approximately 38° and values of the Euler angles lambda (λ) and theta (θ) are approximately 0° (or at least one symmetrical equivalent thereof). In a second example implementation, the lithium niobate material is cut such that a value of the Euler angle theta (θ) is approximately 90° and values of the Euler angles lambda (λ) and mu (µ) are approximately zero (or at least one symmetrical equivalent thereof). In general, the term “approximately” can mean that any of the angles can be within +/-10% of a specified value or less (e.g., within +/- 5%, +/-3%, or +/-2% of a specified value).

In another example, the piezoelectric layer 128 is formed using lithium tantalate. In this case, the lithium tantalate material is cut such that a value of the Euler angle mu (µ) is approximately 42° and values of the Euler angles lambda (λ) and theta (θ) are approximately 0° (or at least one symmetrical equivalent thereof). In general, the term “approximately” can mean that any of the angles can be within +/-10% of a specified value or less (e.g., within +/- 5%, +/-3%, or +/-2% of a specified value). The Euler angles are further described with respect to FIGS. 3-2.

The substrate layer 126 includes one or more sublayers that can support passivation, temperature management, power handling, mode suppression, and so forth. As an example, the substrate layer 126 can include at least one charge-trapping layer 318 (e.g., at least one trap-rich layer), at least one support layer 320, or some combination thereof. These sublayers can be considered part of the substrate layer 126 or their own separate layers. In one example implementation, the substrate layer 126 includes a single support layer 320, which is formed using silicon (Si) material.

The charge-trapping layer 318 can trap induced charges at the interface between the compensation and support layer in order to, for example, suppress nonlinear substrate effects. The charge-trapping layer 318 can include at least one polysilicon (poly-Si) layer (e.g., a polycrystalline silicon layer or a multicrystalline silicon layer), at least one amorphous silicon layer, at least one silicon nitride (SiN) layer, at least one silicon oxynitride (SiON) layer, at least one aluminium nitride (AlN) layer, diamond-like carbon (DLC), diamond, or some combination thereof.

The support layer 320 can reduce the amount of energy that leaks into the substrate layer 126. In some implementations, the support layer 320 can also act as a compensation layer 318. In general, the support layer 320 is composed of material that is non-conducting and provides isolation. For example, the support layer 320 can be formed using silicon (Si) material (e.g., a doped high-resistive silicon material), sapphire material (e.g., aluminium oxide (Al₂O₃)), silicon carbide (SiC) material, fused silica material, quartz, glass, diamond, or some combination thereof. In some implementations, the support layer 320 has a relatively similar thermal expansion coefficient (TEC) as the piezoelectric layer 128. The support layer 320 can also have a particular crystal orientation to support the suppression or attenuation of spurious modes.

In some aspects, the microacoustic filter 124 can be considered a resonator. Sometimes the microacoustic filter 124 can be connected to other resonators associated with different layer stacks than the microacoustic filter 124. In other aspects, the microacoustic filter 124 can be implemented as multiple interconnected resonators, which use the same layers (e.g., the substrate layer 126, the piezoelectric layer 128, and/or the dielectric 130).

FIGS. 3-2 illustrates example Euler angles that define an orientation of the piezoelectric layer 128 relative to a crystalline structure of the material that forms the piezoelectric layer 128. In this example, the material that forms the piezoelectric layer 128 includes lithium niobate. A first crystalline (X′) axis 326, a second crystalline (Y′) axis 328, and a third crystalline (Z′) axis 330 are fixed along crystallographic axes of a lithium niobate crystal. A first rotation 324-1 is applied to rotate the first crystalline X′ axis 326 and the second crystalline Y′ axis 328 about the third crystalline Z′ axis 330. In particular, the first rotation 324-1 rotates the first crystalline X′ axis 326 in a direction of the second crystalline Y′ axis 328. The angle associated with the first rotation 324-1 characterizes one of the Euler angles, which is represented by Euler angle lambda (λ) 332. The resulting rotated axes are represented by a new set of axes: an X″ axis 334, a Y″ axis 336, and a Z″ axis 338. As shown in FIGS. 3-2, the third crystalline Z′ axis 330 remains unchanged by the first rotation 324-1 such that the third crystalline Z′ axis 330 is equal to the Z″ axis 338.

In a second rotation 324-2, the Y″ axis 336 and the Z″ axis 338 are rotated about the X″ axis 334 by another Euler angle, which is represented by Euler angle mu (µ) 340. In this case, the Y″ axis 336 is rotated in the direction of the Z″ axis 338. The resulting rotated axes are represented by a new set of axes: an X‴ axis 342, a Y‴ axis 344, and a Z‴ axis 346. As shown in FIGS. 3-2, the X″ axis 334 remains unchanged by the second rotation 324-2 such that the X″ axis 334 is equal to the X‴ axis 342.

In a third rotation 324-3, the X‴ axis 342 and the Y‴ 344 axis are rotated about the Z‴ axis 346 by an additional Euler angle, which is represented by Euler angle theta (θ) 348. In this case, the X‴ axis 342 is rotated in the direction of the Y‴ axis 344. The resulting rotated axes are represented by a first filter (X) axis 350, a second filter (Y) axis 352, and a third filter (Z) axis 354, which respectively correspond to the first (X) axis 406, the second (Y) axis 408, and the third (Z) axis 412 of FIG. 4. As shown in FIGS. 3-2, the Z‴ axis 346 remains unchanged by the third rotation 324-3 such that the Z‴ axis 346 is equal to the third filter Z axis 354. The microacoustic filter 124 is further described with respect to FIG. 4.

FIG. 4 illustrates a first example implementation of the microacoustic filter 124 with the dielectric 130 partially suspending the piezoelectric layer 128 apart from the substrate layer 126. A three-dimensional perspective view 400-1 of the microacoustic filter 124 is shown at the top of FIG. 4, and a two-dimensional cross-section view 400-2 of the microacoustic filter 124 is shown at the bottom of FIG. 4. The microacoustic filter 124 includes the piezoelectric layer 128, the electrode structure 302, the dielectric 130, and the substrate layer 126. The electrode structure 302 can include one or more interdigital transducers 304.

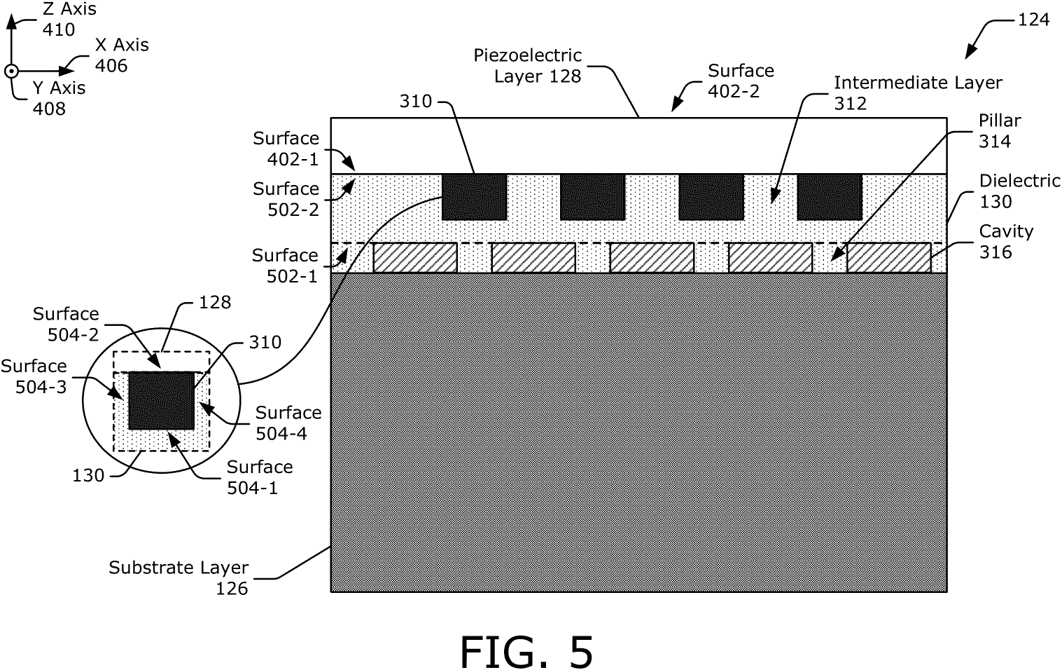

In the depicted configuration shown in the two-dimensional cross-section view 400-2, the dielectric 130 covers (e.g., is in physical contact with, or is at least proximate to) a surface 402-1 of the piezoelectric layer 128, which is facing the substrate layer 126. The intermediate layer 312 and pillars 314 of the dielectric 130 are further described with respect to FIG. 5.

The dielectric 130 defines a cavity 316 between the piezoelectric layer 128 and the substrate layer 126. In some cases, the cavity 316 can be considered a collection of multiple cavities that do not intersect. In other cases, the cavity 316 can be considered a single cavity with intersecting branches. Sometimes a width of the cavity 316 can be approximately equal to a width of a gap that is present between adjacent fingers 310 of the electrode structure 302. In general, the term “approximately” can mean that any of the widths can be within +/-10% of a specified value or less (e.g., within +/- 5%, +/-3%, or +/-2% of a specified value). In other implementations, the width of the cavity 316 can be greater than the width of the gap between adjacent fingers 310, as further described with respect to FIG. 5.

In the three-dimensional perspective view 400-1, the interdigital transducer 304 is shown to have the two comb-shaped structures 306-1 and 306-2 with fingers 310 extending from two busbars 308 towards each other. The fingers 310 are arranged in an interlocking manner in between the two busbars 308 of the interdigital transducer 304 (e.g., arranged in an interdigitated manner). In other words, the fingers 310 connected to a first busbar 308 extend towards a second busbar 308 but do not connect to the second busbar 308. Likewise, fingers 310 connected to the second busbar 308 extend towards the first busbar 308 but do not connect to the first busbar 308.

In the direction along the busbars 308, there is an overlap region including a central region where a portion of one finger 310 overlaps with a portion of an adjacent finger 310. This central region, including the overlap, may be referred to as the aperture, track, or active region where electric fields are produced between fingers 310 to cause an acoustic wave 412 to form at least in this region of the piezoelectric layer 128.

A physical periodicity of the fingers 310 is referred to as a pitch 404 of the interdigital transducer 304. The pitch 404 may be indicated in various ways. For example, in certain aspects, the pitch 404 may correspond to a magnitude of a distance between adj acent fingers 310 of the interdigital transducer 304 in the central region. This distance may be defined, for example, as the distance between center points of each of the fingers 310. The distance may be generally measured between a right (or left) edge of one finger 310 and the right (or left) edge of an adjacent finger 310 when the fingers 310 have uniform widths. In certain aspects, an average of distances between adjacent fingers 310 of the interdigital transducer 304 may be used for the pitch 404. The frequency is determined at least in part by properties of the microacoustic filter 124.

In the three-dimensional perspective view 400-1, the microacoustic filter 124 is defined by a first (X) axis 406, a second (Y) axis 408, and a third (Z) axis 410. The first axis 406 and the second axis 408 are parallel to a planar surface of the piezoelectric layer 128, and the second axis 408 is perpendicular to the first axis 406. The third axis 410 is normal (e.g., perpendicular) to the planar surface of the piezoelectric layer 128. The busbars 308 of the interdigital transducer 304 are oriented to be parallel to the first axis 406. The fingers 310 of the interdigital transducer 304 are orientated to be parallel to the second axis 408. The fingers 310 generate an electric field in a direction that is substantially parallel to the first axis 406. This electric field can generate a quasi-stationary acoustic wave 412, which is spatially trapped within the piezoelectric layer 128 and is present between adjacent fingers 310 of the electrode structure 302.

Although not shown in FIG. 4, some examples of the microacoustic filter 124 can dispose the electrode structure 302 on a second surface 402-2 of the piezoelectric layer 128 that faces away from the substrate layer 126. In other words, the piezoelectric layer 128 can be disposed between the electrode structure 302 and the dielectric 130. While this may make it easier to fabricate the microacoustic filter 124, the position of the electrode structure 302 on the second surface 402-2 of the piezoelectric layer prevents further adjustment of a frequency response of the microacoustic filter 124 by trimming the piezoelectric layer 128 (e.g., by reducing a thickness of the piezoelectric layer 128).

Alternatively, other examples of the microacoustic filter 124 dispose the electrode structure 302 between the piezoelectric layer 128 and the dielectric 130, as shown in FIG. 4. In this case, the electrode structure 302 is positioned such that it is in contact with the first surface 402-1 of the piezoelectric layer 128 that faces the substrate layer 126. This enables the second surface 402-2 of the piezoelectric layer 128 to be trimmed after fabrication of the electrode structure 302. By trimming the piezoelectric layer 128, a frequency response of the microacoustic filter 124 can be tuned.

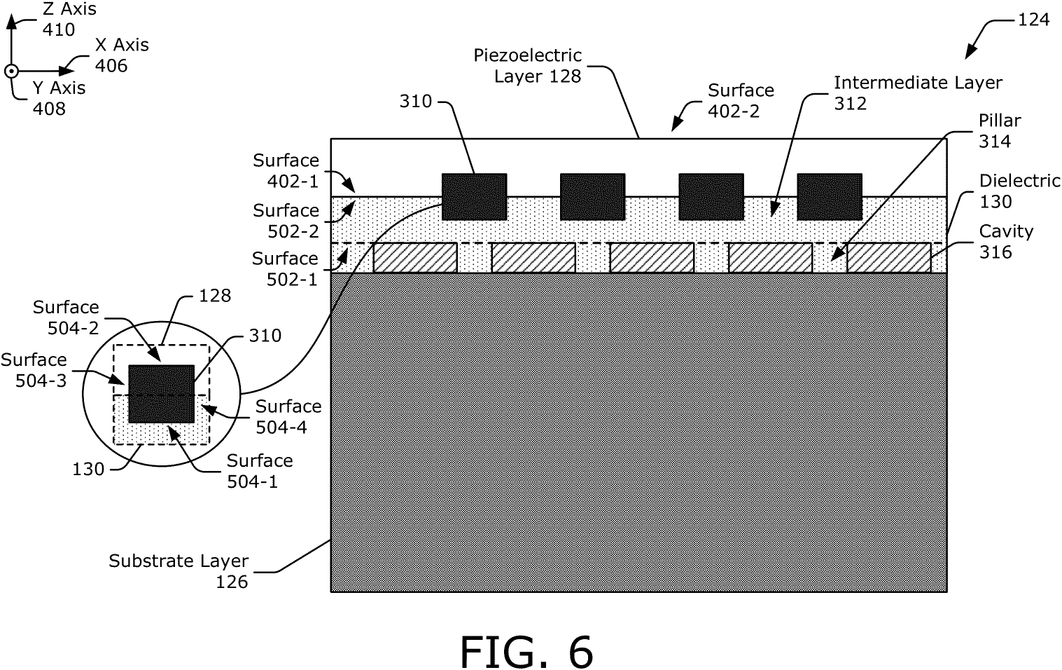

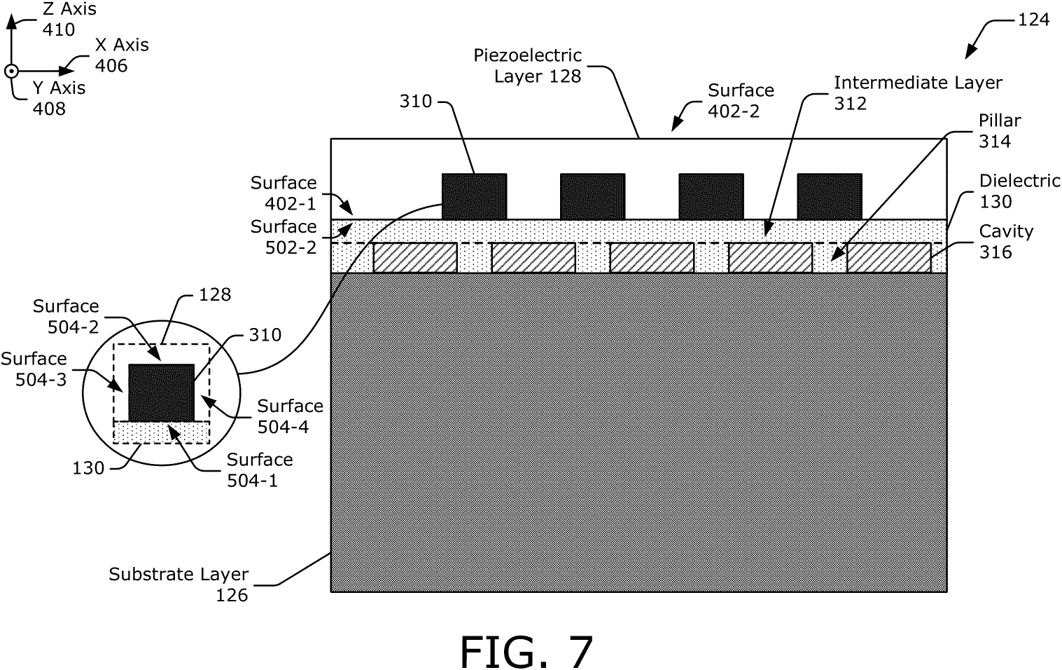

There are various ways in which the electrode structure 302 can be positioned between the piezoelectric layer 128 and the dielectric 130. In a first example implementation, the electrode structure 302 is embedded within the dielectric 130 and is in contact with the piezoelectric layer 128, as further described with respect to FIG. 5. In a second example implementation, the electrode structure 302 is partially embedded within the piezoelectric layer 128 and partially embedded within the piezoelectric layer 128, as further described with respect to FIG. 6. In a third example implementation, the electrode structure 302 is embedded within the piezoelectric layer 128 and is in contact with the dielectric 130, as further described with respect to FIG. 7.

During operation, the microacoustic filter 124 accepts a radio-frequency signal, such as the pre-filter transmit signal 224 or the pre-filter receive signal 230 shown in FIG. 2. The electrode structure 302 excites an acoustic wave 412 within the piezoelectric layer 128 using the inverse piezoelectric effect. For example, the interdigital transducer 304 in the electrode structure 302 generates an alternating electric field based on the accepted radio-frequency signal. The piezoelectric layer 128 enables the acoustic wave 412 to be formed in response to the alternating electric field generated by the interdigital transducer 304. In other words, the piezoelectric layer 128 causes, at least partially, the acoustic wave 412 to form responsive to electrical stimulation by one or more interdigital transducers 304.

The acoustic wave 412 forms within the piezoelectric layer 128 and interacts with the interdigital transducer 304 or another interdigital transducer within the electrode structure 302 (not shown in FIG. 4). The acoustic wave 412 that forms can be a standing wave. In some implementations, two reflectors within the electrode structure 302 cause the acoustic wave 412 to be formed as a standing wave across a portion of the piezoelectric layer 128. In other implementations, the acoustic wave 412 propagates across the piezoelectric layer 128 from the interdigital transducer 304 to another interdigital transducer (not shown).

Using the piezoelectric effect, the electrode structure 302 generates a filtered radio-frequency signal based on the formed acoustic wave 412. In particular, the piezoelectric layer 128 generates an alternating electric field due to the mechanical stress generated by the propagation of the acoustic wave 412. The alternating electric field induces an alternating current in the other interdigital transducer or the interdigital transducer 304. This alternating current forms the filtered radio-frequency signal, which is provided at an output of the microacoustic filter 124. The filtered radio-frequency signal can include the filtered transmit signal 226 or the filtered receive signal 232 of FIG. 2.

It should be appreciated that while a certain number of fingers are illustrated in FIG. 4, the number of actual fingers and lengths and width of the fingers and busbars may be different in an actual implementation. Such parameters depend on the particular application and desired filter characteristics. In addition, the microacoustic filter 124 can include multiple interconnected electrode structures 302 each including multiple interdigital transducers 304 to achieve a desired passband (e.g., multiple interconnected resonators or interdigital transducers 304 in series or parallel connections to form a desired filter transfer function).

Although not explicitly shown, the electrode structure 302 can also include two or more reflectors. In an example implementation, the interdigital transducer 304 is arranged between two reflectors (not shown). Each reflector within the electrode structure 302 can have two busbars and a grating structure of conductive fingers that each connect to both busbars. In some implementations, the pitch of the reflector can be similar to or the same as the pitch 404 of the interdigital transducer 304. Features of the dielectric 130 are further described with respect to FIG. 5.

FIG. 5 illustrates examples of the intermediate layer 312 and the pillars 314 of the dielectric 130 that partially suspend the piezoelectric layer 128. A dashed line is illustrated in FIG. 5 to distinguish between the intermediate layer 312 and the pillars 314 of the dielectric 130. The intermediate layer 312 covers or abuts at least a portion of the surface 402-1 of the piezoelectric layer 128. A first surface 502-1 of the intermediate layer 312 faces towards the substrate layer 126, and a second surface 502-2 of the intermediate layer 312 faces away from the substrate layer 126 (e.g., faces towards the piezoelectric layer 128). The second surface 502-2 of the intermediate layer 312 at least partially abuts the surface 402-1 of the piezoelectric layer 128. In general, the intermediate layer 312 represents a portion of the dielectric 130 that is disposed on the surface 402-1 of the piezoelectric layer 128 and/or disposed on the pillars 314.

Along the first (X) axis 406 and/or the second (Y) axis 408, the intermediate layer 312 can be implemented as one contiguous piece. Alternatively, the intermediate layer 312 can be implemented using multiple pieces that are physically separated from each other along the first (X) axis 406 and/or the second (Y) axis 408. In general, the intermediate layer 312 is disposed on the pillars 314. In some cases, the intermediate layer 312 is also disposed on at least a portion of the electrode structure 302, such as across at least a portion of the fingers 310, at least a portion of the busbar 308, and/or at least a portion of the reflectors, or other parts of the chip. In example implementations, the intermediate layer 312 is disposed across a majority of the length of the fingers 310.

The pillars 314 represent a portion of the dielectric 130 that is disposed between the first surface 502-1 of the intermediate layer 312 and the substrate layer 126. In particular, the pillars 314 include the portion of the dielectric 130 that extends past a plane defined by the first surface 502-1 of the intermediate layer 312. In some implementations, the pillars 314 abut the substrate layer 126.

In general, the dielectric 130 includes three or more pillars 314. The pillars 314 are distributed at different points along the first (X) axis 406. The positions of one or more of the pillars 314 along the first (X) axis 406 can correspond with the positions of one or more fingers 310. Sometimes a quantity of pillars 314 is less than a quantity of fingers 310. In this case, the pillars 314 can be positioned along the first (X) axis 406 at points that correspond with a subset of the fingers 310. The term “subset” can refer to a “proper subset,” such that the subset can have fewer items than a set. Other times, a quantity of pillars 314 is at least equal to the quantity of fingers 310. In this case, the position of each finger 310 along the first (X) axis 406 can be associated with a position of at least one pillar 314.

In the depicted configuration, the pillars 314 are positioned “below” at least a portion of the fingers 310. In other words, a pillar 314 is positioned between a finger 310 and the substrate layer 126 along the third (Z) axis 410. Sometimes, a center point of the pillar 314 aligns with a center point of a corresponding finger 310 along the third (Z) axis 410.

Along the second (Y) axis 408, the pillar 314 can be implemented as one contiguous piece. Alternatively, the pillar 314 can be implemented using multiple pieces that are physically separated from each other along the second (Y) axis 408. In some implementations, a length of the pillar 314 along the second (Y) axis 408 can be approximately equal to a length of a finger 310 (e.g., within +/- 10%, +/- 5%, +/- 3%, or +/- 2% of the length of the finger 310). In other implementations, the length of the pillar 314 along the second (Y) axis 408 is less than the length of the finger 310 but greater than half the length of the finger 310. In still other implementations, the length of the pillar 314 is greater than the length of the finger 310.

In the depicted configuration, the fingers 310 of the electrode structure 302 are shown to have four surfaces 504-1, 504-2, 504-3, and 504-4. Although depicted with a rectangular cross section, the cross section of the fingers 310 can be any shape, including a triangular shape or a rounded shape. The surfaces 504-1 and 504-2 can be substantially parallel to each other. Also, the surfaces 504-3 and 504-4 can be substantially parallel to each other and normal to the surfaces 504-1 and 504-2. The surface 504-1 faces the substrate layer 126 and can be in contact with the dielectric 130. The surface 504-2 is opposite the surface 504-1 and faces away from the substrate layer 126. The surface 504-2 is at least in contact with the piezoelectric layer 128. In some aspects, the third (Z) axis 410 is substantially normal to the surfaces 504-1 and 504-2. The surfaces 504-3 and 504-4 are adjacent to the surfaces 504-1 and 504-2. The first (X) axis 406 can be substantially normal to the surfaces 504-3 and 504-4.

Although not explicitly shown, the electrode structure 302 can also have two other surfaces, which are substantially normal to the second (Y) axis 408. The dielectric 130 can optionally cover or abut at least a portion of these surfaces.

As shown in FIG. 5, the surfaces 504-1, 504-3, and 504-4 of the fingers 310 are in contact with the dielectric 130. In contrast, the surface 504-2 of the fingers 310 is in contact with the surface 402-1 of the piezoelectric layer 128. In this way, the electrode structure 302 is at least partially embedded within the dielectric 130. In particular, the electrode structure 302 is not buried within the piezoelectric layer 128. Even with the electrode structure 302 embedded within the dielectric 130, the microacoustic filter 124 can meet a target electromechanical coupling factor (k²). One way to define the electromechanical coupling factor is further shown in Equation 1 below:

$${k}^{2} = \frac{{\left(\frac{π}{2}\right)}^{2} \left(\frac{f s}{f p}\right) \left({f}_{p} - {f}_{s}\right)}{{f}_{p}} \qquad \text{Equation 1}$$

where fₛ is the resonance frequency and fₚ is the antiresonance frequency. As an example, the electromechanical coupling factor of the microacoustic filter 124 can be at least 25%. To improve the electromechanical coupling factor, the electrode structure 302 can be at least partially embedded within the piezoelectric layer 128, as further described with respect to FIGS. 6 and 7.

The microacoustic filter 124 of FIG. 5 is similar to the microacoustic filter 124 of FIG. 4, except the width of the cavity 316 is greater than a width of the gap between adjacent fingers 310. In other words, the width of the cavity 316 extends past the width of the gap. Explained another way, the widths of the pillars 314 are less than the widths of the fingers 310. For example, the width of the pillars 314 can be approximately equal to 75%, 50%, or 30% of the width of the finger 310. In general, the width of the cavity 316 is constrained by a target width of the pillars 314 for providing structural support for partially suspending the piezoelectric layer 128. The microacoustic filter 124 can also include additional layers, as further described with respect to FIG. 8.

Although not explicitly shown, the dielectric 130 can be formed without cavities below the busbar 308 or at outer edges of the piezoelectric layer 128. In other words, the dielectric 130 can be continuous along the third (Z) axis 410 across some portions of the piezoelectric layer 128 and/or some portions of the electrode structure 302.

In an example implementation, the microacoustic filter 124 is designed to have a resonant frequency of approximately 4 GHz. The piezoelectric layer 128 can have a thickness of approximately 400 nanometers. The fingers 310 can have a thickness of approximately 100 nanometers. The thickness of the intermediate layer 312 between the surfaces 502-1 and 502-2 can be approximately 100 nanometers. The thickness of the pillars 314 can be approximately 100 nanometers. A width of the pitch 404 can be approximately 3.5 micrometers. The width of the fingers 310 along the first (X) axis 406 can be between approximately 100 nanometers and 2 micrometers. The width of the pillars 314 can be between approximately 100 nanometers and 2 micrometers. In general, the term “approximately” can mean that any of the dimensions can be within +/-10% of a specified value or less (e.g., within +/- 5%, +/-3%, or +/-2% of a specified value). Other example implementations of the microacoustic filter 124 are further described with respect to FIGS. 6 to 8.

FIG. 6 illustrates a second example implementation of a microacoustic filter 124 with the dielectric 130 partially suspending the piezoelectric layer 128. The microacoustic filter 124 of FIG. 6 is similar to the microacoustic filter 124 of FIG. 5, except the fingers 310 of FIG. 6 are partially embedded within the dielectric 130 partially embedded within the piezoelectric layer 128. The surface 504-1 of each finger 310 is in contact with the dielectric 130, and the surface 504-2 of each finger 310 is in contact with the piezoelectric layer 128. Also, the surfaces 504-3 and 504-4 are in contact with the dielectric 130 and the piezoelectric layer 128. By at least partially embedding the electrode structure 302 within the piezoelectric layer 128, the microacoustic filter 124 of FIG. 6 can have a higher electromechanical coupling factor compared to the microacoustic filter 124 of FIG. 5. In an example implementation, the electromechanical coupling factor of the microacoustic filter 124 of FIG. 6 can be approximately 30%.

FIG. 7 illustrates a third example implementation of a microacoustic filter 124 with the dielectric 130 partially suspending the piezoelectric layer 128. The microacoustic filter 124 of FIG. 7 is similar to the microacoustic filters 124 of FIGS. 5 and 6, except the fingers 310 of FIG. 7 are at least partially embedded within the dielectric 130. In particular, the electrode structure 302 is not buried within the dielectric 130. As such, the surface 502-1 of each finger 310 is in contact with the dielectric 130, and the surfaces 502-2 to 502-4 of each finger 310 are in contact with the piezoelectric layer 128. The microacoustic filter 124 of FIG. 7 can have a higher electromechanical coupling factor compared to the microacoustic filters 124 of FIGS. 5 and 6.

In FIGS. 5 to 7, the electrode structure 302 is shown to be in direct physical contact with the piezoelectric layer 128. In alternative implementations, a dielectric layer (not shown) is present between the electrode structure 302 and the piezoelectric layer 128. This dielectric layer can be implemented using similar or different material as the dielectric 130. In an example implementation, a thickness of this dielectric layer is approximately 10 nanometers or less (e.g., 10, 8, 5, or 2 nanometers). In general, the term “approximately” can mean that the thickness can be within +/-10% of a specified value or less (e.g., within +/- 5%, +/-3%, or +/-2% of a specified value). The material and thickness of the dielectric layer can be tailored to achieve desired interface properties between the electrode structure 302 and the piezoelectric layer 128.

FIG. 8 illustrates a fourth example implementation of a microacoustic filter 124 with a dielectric 130 that partially suspends a piezoelectric layer 128. The microacoustic filter 124 of FIG. 8 can be similar to the microacoustic filters 124 of FIGS. 5 to 7, with the addition of one or more other layers. The additional layer(s) can include at least one dielectric layer 802, at least one acoustic mirror 804, at least one charge-trapping layer 318, or some combinations thereof.

In the depicted configuration, the dielectric layer 802 is disposed on the surface 402-2 of the piezoelectric layer 128. The dielectric layer 802 can further reduce the temperature coefficient of frequency compared to other implementations of the microacoustic filter 124 that do not include the dielectric layer 802.

The acoustic mirror 804 is disposed between the dielectric 130 and the substrate layer 126. The acoustic mirror 804 includes a layer 806 with a first impedance and a layer 808 with a second impedance that is higher than the first impedance. In an example implementation, the layer 806 is implemented using silicon dioxide, and the layer 808 is implemented using tungsten (W). The acoustic mirror 804 can help confine the acoustic wave 412 to the piezoelectric layer 128. Although not explicitly shown, some example implementations of the microacoustic filter 124 can have multiple acoustic mirrors 804 stacked together between the dielectric 130 and the substrate layer 126.

The charge-trapping layer 318 is generally disposed between the dielectric 130 and the substrate layer 126. In the depicted configuration, the charge-trapping layer 318 is disposed between the acoustic mirror 804 and the substrate layer 126. Although not explicitly shown, some example implementations can include the charge-trapping layer 318 and not include the acoustic mirror 804. In an example implementation, the charge-trapping layer 318 is implemented using polysilicon material. In general, the charge-trapping layer 318 traps induced charges at the interface between the dielectric 130 and the substrate layer 126.

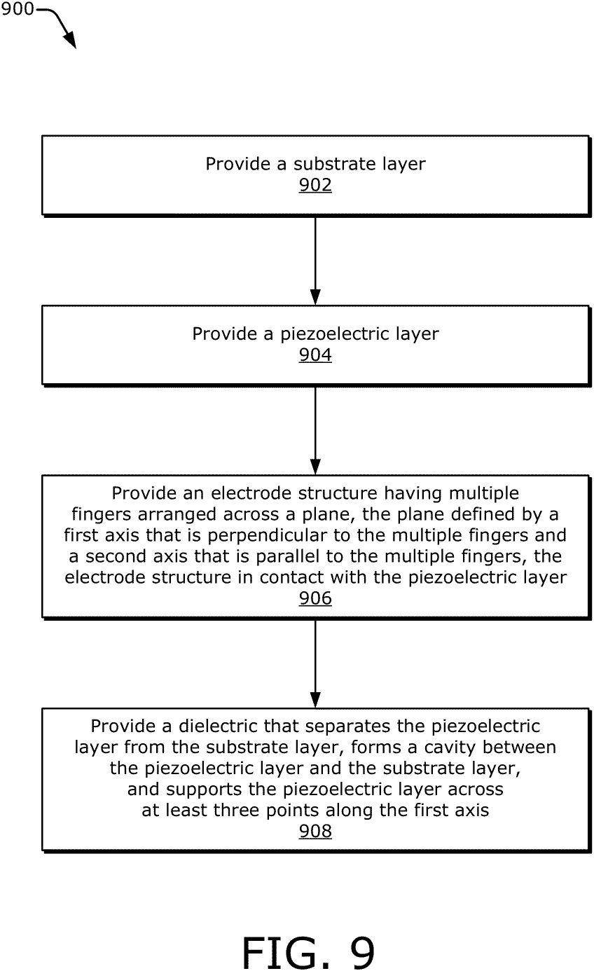

FIG. 9 is a flow diagram illustrating an example process 900 for manufacturing a microacoustic filter 124 with a dielectric that partially suspends a piezoelectric layer. The process 900 is described in the form of a set of blocks 902-908 that specify operations that can be performed. However, operations are not necessarily limited to the order shown in FIG. 9 or described herein, for the operations may be implemented in alternative orders or in fully or partially overlapping manners. Also, more, fewer, and/or different operations may be implemented to perform the process 900, or an alternative process. Operations represented by the illustrated blocks of the process 900 may be performed to manufacture the microacoustic filter 124 (e.g., of FIGS. 1 to 3). More specifically, the operations of the process 900 may be performed, at least in part, to partially suspend a piezoelectric layer 128 using a dielectric 130 (e.g., of FIGS. 4 to 8).

At 902, a substrate layer is provided. For example, a manufacturing process provides a substrate layer 126, as shown in FIGS. 4 to 8. The substrate layer 126 can have a single layer or multiple sublayers. In an example implementation, the substrate layer 126 is implemented using silicon to provide isolation.

At 904, a piezoelectric layer is provided. For example, a manufacturing process provides a piezoelectric layer 128, as shown in FIGS. 4 to 8. The piezoelectric layer 128 can be implemented using materials such as lithium niobate, lithium tantalate, quartz, aluminium nitride, aluminium scandium nitride, or some combination thereof. In some aspects, a structure of the piezoelectric layer 128 is tailored to enable the piezoelectric layer 128 to excite a plate mode, such as an antisymmetric plate mode.

At 906, an electrode structure is provided having multiple fingers arranged across a plane. The plane is defined by a first axis that is perpendicular to the multiple fingers and a second axis that is parallel to the multiple fingers. The electrode structure is in contact with the piezoelectric layer. For example, the manufacturing process provides the electrode structure 302, as shown in FIGS. 4 to 8.

The electrode structure 302 includes multiple fingers 310 arranged across a plane defined by the first (X) axis 406 and the second (Y) axis 408. The first (X) axis is substantially perpendicular to the fingers 310 and is parallel to the direction of acoustic-wave propagation. The second (Y) axis is substantially parallel to the fingers 310. The electrode structure 302 can be formed using an electrically conductive material, such as metal.

In some examples implementation, the electrode structure 302 is disposed on the second surface 402-2 of the piezoelectric layer 128, which faces away from the substrate layer 126. In other example implementations, the electrode structure 302 is disposed between the piezoelectric layer 128 and the dielectric 130. This enables the second surface 402-2 of the piezoelectric layer 128 to be trimmed after fabrication of the electrode structure 302. In both example implementations, the electrode structure 302 is in contact with the piezoelectric layer 128. As such, the electrode structure 302 can optionally be in contact with the dielectric 130.

At 908, a dielectric that separates the piezoelectric layer from the substrate layer is provided. The dielectric defines a cavity between the piezoelectric layer and the substrate layer and supports the piezoelectric layer across at least three points along the first axis. For example, the manufacturing process provides the dielectric 130, which separates the piezoelectric layer 128 from the substrate layer 126, as shown in FIGS. 4 to 8. The dielectric 130 defines the cavity 316 between the piezoelectric layer 128 (e.g., a portion of the piezoelectric layer 128 that is covered by the dielectric 130) and the substrate layer 126 along the third (Z) axis 410. In some implementations, the cavity 316 is positioned below gaps between adjacent fingers 310 of the electrode structure 302. Optionally, the manufacturing process can also provide at least one dielectric layer 802, at least one acoustic mirror 804, at least one charge-trapping layer 318 (of FIG. 6), or some combination thereof.

There are various processes for implementing the microacoustic filter 124. In this case, the manufacturing process can deposit the electrode structure 302 on the piezoelectric layer 128. Next, the manufacturing process can provide the dielectric 130 by depositing the intermediate layer 312 across the piezoelectric layer 128 and the electrode structure 302 and depositing the pillars 314 on the intermediate layer 312. The pillars 314 can be bonded to the substrate layer 126.

Alternatively, the microacoustic filter 124 can be manufactured using an etching process. Prior to bonding the pillars 314 to the substrate layer 126, this example manufacturing process deposits a sacrificial layer across the intermediate layer 312 and the pillars 314. After bonding the pillars 314 and the sacrificial layer to the substrate layer 126, the manufacturing process uses access holes at the front or back of the microacoustic filter 124 to release the sacrificial layer via etching.

Instead of using bonding, another example manufacturing process sequentially deposits each layer of the microacoustic filter 124 of FIG. 5. For example, the manufacturing process deposits a sacrificial layer on the substrate layer 126. The manufacturing process also deposits the dielectric 130 on the sacrificial layer. A metal damascene process can be performed to partially embed the electrode structure 302 within the dielectric 130. The manufacturing process additionally deposits the piezoelectric layer 128 on surfaces of the dielectric 130 and electrode structure 302. The manufacturing process uses etching to release the sacrificial layer.

With the electrode structures 302 disposed on the surface 402-1 of the piezoelectric layer 128, the manufacturing processes described above can also grind, polish, and/or trim the surface 402-2 of the piezoelectric layer 128.

Some aspects are described below.

Aspect 1: An apparatus comprising:

a microacoustic filter comprising:
a substrate layer;
a piezoelectric layer;
an electrode structure in contact with the piezoelectric layer, the electrode structure comprising multiple fingers arranged across a plane having a first axis that is perpendicular to the multiple fingers and a second axis that is parallel to the multiple fingers; and
a dielectric configured to:
   separate the piezoelectric layer from the substrate layer;
   define a cavity between the piezoelectric layer and the substrate layer; and
   support the piezoelectric layer across at least three points along the first axis.

Aspect 2: The apparatus of aspect 1, wherein the dielectric is configured to define the cavity between the substrate layer and at least part of the dielectric.

Aspect 3: The apparatus of aspect 1 or 2, wherein one or more points of the at least three points correspond to a position of one or more fingers of the multiple fingers along the first axis.

Aspect 4: The apparatus of aspect 3, wherein the one or more fingers comprise a subset of the multiple fingers.

Aspect 5: The apparatus of aspect 4, wherein the multiple fingers comprise all fingers of the electrode structure.

Aspect 6: The apparatus of any previous aspect, wherein the dielectric and the piezoelectric layer are adhered together.

Aspect 7: The apparatus of any previous aspect, wherein:
the piezoelectric layer has a surface facing the substrate layer; and
the dielectric comprises:
   an intermediate layer disposed across the surface of the piezoelectric layer, the intermediate layer having a surface facing the substrate layer; and
   at least three pillars extending past a plane defined by the surface of the intermediate layer and toward the substrate layer to define the cavity between the intermediate layer and the substrate layer, the at least three pillars positioned at the at least three points along the first axis.

Aspect 8: The apparatus of aspect 7, wherein a pillar of the at least three pillars is positioned between a finger of the multiple fingers and the substrate layer along a third axis that is perpendicular to the first axis and the second axis.

Aspect 9: The apparatus of aspect 8, wherein:
a width of the pillar is less than a width of the finger; and
a length of the pillar is approximately equal to a length of the finger.

Aspect 10: The apparatus of any previous aspect, wherein:
the electrode structure is at least partially embedded within the dielectric; and
a surface of the electrode structure faces away from the substrate layer and is in contact with a surface of the piezoelectric layer that faces the substrate layer.

Aspect 11: The apparatus of any one of aspects 1 to 9, wherein the electrode structure is partially embedded within the dielectric and partially embedded within the piezoelectric layer.

Aspect 12: The apparatus of any one of aspects 1 to 9, wherein:
the electrode structure is at least partially embedded within the piezoelectric layer; and
a surface of the electrode structure faces towards the substrate layer and is in contact with a surface of the dielectric that faces away from the substrate layer.

Aspect 13: The apparatus of any one of aspects 1 to 9, wherein the electrode structure is disposed on a surface of the piezoelectric layer that faces away from the substrate layer.

Aspect 14: The apparatus of any previous aspect, wherein:
the cavity is at least partially filled with a gas; and
the gas comprises air.

Aspect 15: The apparatus of any previous aspect, wherein the dielectric comprises one or more of the following:
silicon dioxide;
doped silicon dioxide;
silicon nitride;
aluminum oxide; or
aluminum nitride.

Aspect 16: The apparatus of any previous aspect, wherein a thickness of the dielectric is between approximately fifty nanometers and two micrometers.

Aspect 17: The apparatus of any previous aspect, wherein the piezoelectric layer is configured to excite an antisymmetric plate mode.

Aspect 18: The apparatus of any previous aspect, further comprising a dielectric layer disposed on a surface of the piezoelectric layer that faces away from the substrate layer.

Aspect 19: The apparatus of any previous aspect, further comprising at least one acoustic mirror disposed between the dielectric and the substrate layer.

Aspect 20: The apparatus of any previous aspect, further comprising a charge-trapping layer disposed between the dielectric and the substrate layer.

Aspect 21: The apparatus of any previous aspect, wherein:
the microacoustic filter comprises multiple cascaded resonators; and
a resonator of the multiple cascaded resonators comprises the substrate layer, the piezoelectric layer, the electrode structure, and the dielectric.

Aspect 22: The apparatus of any previous aspect, further comprising:

a wireless transceiver coupled to at least one antenna, the wireless transceiver comprising the microacoustic filter and configured to filter, using the microacoustic filter, a wireless signal communicated via the at least one antenna.

Aspect 23: An apparatus comprising:

a microacoustic filter configured to generate a filtered signal from a radio-frequency signal, the microacoustic filter comprising:
means for converting the radio-frequency signal to an acoustic wave and converting a formed acoustic wave into the filtered signal;
means for exciting an antisymmetric plate mode to produce the formed acoustic wave,
means for confining energy of the antisymmetric plate mode within the means for exciting; and
means for partially suspending the means for exciting apart from the means for confining energy.

Aspect 24: The apparatus of aspect 23, wherein:
the means for converting comprises means for generating an electric field in a direction that is parallel to a first axis; and
the means for partially suspending comprises:
   means for defining a cavity between the means for exciting and the means for confining energy; and
   means for supporting the means for exciting across at least three points along the first axis.

Aspect 25: A method of manufacturing a microacoustic filter, the method comprising:
providing a substrate layer;
providing a piezoelectric layer;
providing an electrode structure having multiple fingers arranged across a plane, the plane defined by a first axis that is perpendicular to the multiple fingers and a second axis that is parallel to the multiple fingers, the electrode structure in contact with the piezoelectric layer; and
providing a dielectric that separates the piezoelectric layer from the substrate layer, defines a cavity between the piezoelectric layer and the substrate layer, and supports the piezoelectric layer across at least three points along the first axis.

Aspect 26: The method of aspect 25, wherein:
the providing of the electrode structure comprises providing the electrode structure such that the electrode structure is in contact with a first surface of the piezoelectric layer that faces the substrate layer, and
the method further comprises:
   trimming a second surface of the piezoelectric layer that is opposite the first surface.

Aspect 27: A microacoustic filter comprising:
an electrode structure comprising multiple fingers arranged across a plane having a first axis that is perpendicular to the multiple fingers and a second axis that is parallel to the multiple fingers;
a substrate layer;
a piezoelectric layer having a surface that faces the substrate layer; and
a dielectric comprising:
   an intermediate layer disposed across the surface of the piezoelectric layer, the intermediate layer having a surface facing the substrate layer; and
   at least three pillars extending past a plane defined by the surface of the intermediate layer and toward the substrate layer to define a cavity between the intermediate layer and the substrate layer, the at least three pillars positioned across at least three points along the first axis.

Aspect 28: The microacoustic filter of aspect 27, wherein the electrode structure is positioned on a side of the piezoelectric layer that faces the substrate layer.

Aspect 29: The microacoustic filter of aspect 27 or 28, wherein the piezoelectric layer has a crystalline structure operative to excite a plate mode.

Aspect 30: The microacoustic filter of aspect 29, wherein:
a third axis is normal to the first axis and the second axis;
an orientation of the first axis, the second axis, and the third axis is relative to the crystalline structure of the piezoelectric layer as defined by Euler angles lambda, mu, and theta; and
the piezoelectric layer comprises:
   lithium niobate with a value of the Euler angle lambda being approximately 0°, a value of the Euler angle mu being approximately 38°, and a value of the Euler angle theta being approximately 0°;
   the lithium niobate with the value of the Euler angle lambda being approximately 0°, the value of the Euler angle mu being approximately 0°, and the value of the Euler angle theta being approximately 90°; or
   lithium tantalate with the value of the Euler angle lambda being approximately 0°, the value of the Euler angle mu being approximately 42°, and a value of the Euler angle theta being approximately 0°.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
a microacoustic filter comprising:
a substrate layer;
a piezoelectric layer;
an electrode structure in contact with the piezoelectric layer, the electrode structure comprising multiple fingers arranged across a plane having a first axis that is perpendicular to the multiple fingers and a second axis that is parallel to the multiple fingers; and
a dielectric configured to:
separate the piezoelectric layer from the substrate layer;
define a cavity between the piezoelectric layer and the substrate layer; and
support the piezoelectric layer across at least three points along the first axis.

2. The apparatus of claim 1, wherein the dielectric is configured to define the cavity between the substrate layer and at least part of the dielectric.

3. The apparatus of claim 1, wherein one or more points of the at least three points correspond to a position of one or more fingers of the multiple fingers along the first axis.

4. The apparatus of claim 3, wherein the one or more fingers comprise a subset of the multiple fingers.

5. The apparatus of claim 4, wherein the multiple fingers comprise all fingers of the electrode structure.

6. The apparatus of claim 1, wherein the dielectric and the piezoelectric layer are adhered together.

7. The apparatus of claim 1, wherein:
the piezoelectric layer has a surface facing the substrate layer; and
the dielectric comprises:
an intermediate layer disposed across the surface of the piezoelectric layer, the intermediate layer having a surface facing the substrate layer; and
at least three pillars extending past a plane defined by the surface of the intermediate layer and toward the substrate layer to define the cavity between the intermediate layer and the substrate layer, the at least three pillars positioned at the at least three points along the first axis.

8. The apparatus of claim 7, wherein a pillar of the at least three pillars is positioned between a finger of the multiple fingers and the substrate layer along a third axis that is perpendicular to the first axis and the second axis.

9. The apparatus of claim 8, wherein:
a width of the pillar is less than a width of the finger; and
a length of the pillar is approximately equal to a length of the finger.

10. The apparatus of claim 1, wherein:
the electrode structure is at least partially embedded within the dielectric; and
a surface of the electrode structure faces away from the substrate layer and is in contact with a surface of the piezoelectric layer that faces the substrate layer.

11. The apparatus of claim 1, wherein the electrode structure is partially embedded within the dielectric and partially embedded within the piezoelectric layer.

12. The apparatus of claim 1, wherein:
the electrode structure is at least partially embedded within the piezoelectric layer; and
a surface of the electrode structure faces towards the substrate layer and is in contact with a surface of the dielectric that faces away from the substrate layer.

13. The apparatus of claim 1, wherein the electrode structure is disposed on a surface of the piezoelectric layer that faces away from the substrate layer.

14. The apparatus of claim 1, wherein:
the cavity is at least partially filled with a gas; and
the gas comprises air.

15. The apparatus of claim 1, wherein the dielectric comprises one or more of the following:
silicon dioxide;
doped silicon dioxide;
silicon nitride;
aluminum oxide; or
aluminum nitride.

16. The apparatus of claim 1, wherein a thickness of the dielectric is between approximately fifty nanometers and two micrometers.

17. The apparatus of claim 1, wherein the piezoelectric layer is configured to excite an antisymmetric plate mode.

18. The apparatus of claim 1, further comprising a dielectric layer disposed on a surface of the piezoelectric layer that faces away from the substrate layer.

19. The apparatus of claim 1, further comprising at least one acoustic mirror disposed between the dielectric and the substrate layer.

20. The apparatus of claim 1, further comprising a charge-trapping layer disposed between the dielectric and the substrate layer.

21. The apparatus of claim 1, wherein:
the microacoustic filter comprises multiple cascaded resonators; and
a resonator of the multiple cascaded resonators comprises the substrate layer, the piezoelectric layer, the electrode structure, and the dielectric.

22. The apparatus of claim 1, further comprising:
a wireless transceiver coupled to at least one antenna, the wireless transceiver comprising the microacoustic filter and configured to filter, using the microacoustic filter, a wireless signal communicated via the at least one antenna.

23. An apparatus comprising:
a microacoustic filter configured to generate a filtered signal from a radio-frequency signal, the microacoustic filter comprising:
means for converting the radio-frequency signal to an acoustic wave and converting a formed acoustic wave into the filtered signal;
means for exciting an antisymmetric plate mode to produce the formed acoustic wave,
means for confining energy of the antisymmetric plate mode within the means for exciting; and
means for partially suspending the means for exciting apart from the means for confining energy.

24. The apparatus of claim 23, wherein:
the means for converting comprises means for generating an electric field in a direction that is parallel to a first axis; and
the means for partially suspending comprises:
means for defining a cavity between the means for exciting and the means for confining energy; and
means for supporting the means for exciting across at least three points along the first axis.

25. A method of manufacturing a microacoustic filter, the method comprising:
providing a substrate layer;
providing a piezoelectric layer;
providing an electrode structure having multiple fingers arranged across a plane, the plane defined by a first axis that is perpendicular to the multiple fingers and a second axis that is parallel to the multiple fingers, the electrode structure in contact with the piezoelectric layer; and
providing a dielectric that separates the piezoelectric layer from the substrate layer, defines a cavity between the piezoelectric layer and the substrate layer, and supports the piezoelectric layer across at least three points along the first axis.

26. The method of claim 25, wherein:
the providing of the electrode structure comprises providing the electrode structure such that the electrode structure is in contact with a first surface of the piezoelectric layer that faces the substrate layer, and
the method further comprises:
trimming a second surface of the piezoelectric layer that is opposite the first surface.

27. A microacoustic filter comprising:
an electrode structure comprising multiple fingers arranged across a plane having a first axis that is perpendicular to the multiple fingers and a second axis that is parallel to the multiple fingers;
a substrate layer;
a piezoelectric layer having a surface that faces the substrate layer; and
a dielectric comprising:
an intermediate layer disposed across the surface of the piezoelectric layer, the intermediate layer having a surface facing the substrate layer; and
at least three pillars extending past a plane defined by the surface of the intermediate layer and toward the substrate layer to define a cavity between the intermediate layer and the substrate layer, the at least three pillars positioned across at least three points along the first axis.

28. The microacoustic filter of claim 27, wherein the electrode structure is positioned on a side of the piezoelectric layer that faces the substrate layer.

29. The microacoustic filter of claim 27, wherein the piezoelectric layer has a crystalline structure operative to excite a plate mode.

30. The microacoustic filter of claim 29, wherein:
a third axis is normal to the first axis and the second axis;
an orientation of the first axis, the second axis, and the third axis is relative to the crystalline structure of the piezoelectric layer as defined by Euler angles lambda, mu, and theta; and
the piezoelectric layer comprises:
lithium niobate with a value of the Euler angle lambda being approximately 0°, a value of the Euler angle mu being approximately 38°, and a value of the Euler angle theta being approximately 0°;
the lithium niobate with the value of the Euler angle lambda being approximately 0°, the value of the Euler angle mu being approximately 0°, and the value of the Euler angle theta being approximately 90°; or
lithium tantalate with the value of the Euler angle lambda being approximately 0°, the value of the Euler angle mu being approximately 42°, and a value of the Euler angle theta being approximately 0°.
